(19) United States
(12) Patent Application Publication
(10) Pub. No.: US 2016/0376145 A1
(43) Pub. Date: Dec. 29, 2016

(54) METHOD FOR MANUFACTURING A MICROMECHANICAL STRUCTURE AND A COMPONENT HAVING THIS MICROMECHANICAL STUCTURE

(71) Applicant: Robert Bosch GmbH, Stuttgart (DE)

(72) Inventors: Uwe Hansen, Tuebingen (DE); Sebastian Schuler-Watkins, Herrenberg (DE)

(21) Appl. No.: 15/192,185

(22) Filed: Jun. 24, 2016

(30) Foreign Application Priority Data
Jun. 25, 2015 (DE) 102015211778.2

(51) Int. Cl. B81B 7/00; G01D 11/00; B81C 1/00

(52) U.S. Cl. CPC B81B 7/0058; B81C 1/00523; G01D 11/00; B81B 2201/0264; B81B 2201/0235; B81B 2201/0242; B81C 2201/0123

(57) ABSTRACT

A method for manufacturing a micromechanical component and a micromechanical component. The micromechanical component includes a sensor substrate and a cap situated thereon. For creating the cap, a plurality of openings is introduced into a cap substrate in a delimited area on the surface of the front side in the form of microperforations. The openings end in the cap substrate, i.e. they do not go all the way through the cap substrate and are therefore shallow. The cap substrate is then placed on the sensor substrate, whereby the front side of the cap substrate including the plurality of openings is directed toward the sensor substrate. A portion of the cap substrate is removed from its back side by back-thinning using a grinding process or another semiconductor process. The removal of the cap substrate material from the back side creates access to the openings.

### CROSS REFERENCE

The present application claims the benefit under 35 U.S.C. §119 of German Patent Application No. DE 102015211778.2 filed on Jun. 25, 2015, which is expressly incorporated herein by reference in its entirety.

### FIELD

The present invention relates to a method for manufacturing a micromechanical component including a cap structure and a micromechanical component manufactured using this method.

### BACKGROUND INFORMATION

Micromechanical sensors such as pressure sensors, for example, require for sensor detection a media access from the surroundings to the sensor element. This necessary media access is generally achieved by a perforation in the cap which is situated above the sensor for the protection of the sensor element.

When very large perforations are used, with the use of the sensor, there is a risk that dust and water may penetrate the cap, so that under some conditions the accurate detection of sensor variables is threatened. One remedy to this problem might be the creation of very small openings for the passage of media. However, since such small openings are generally created with the aid of micromechanical etching processes, there is a risk when these openings are created after the capping that the sensor element may be damaged by the required etching process.

However, it is not easy to create small openings before capping since the handling during the application and the subsequent molding process during packaging may damage the fine structures generated in the cap and therefore render them useless.

The present invention provides an approach to create a cap including a plurality of small openings without adversely affecting the covered sensor element and/or the media access during processing.

### SUMMARY

The present invention relates to a method for manufacturing a micromechanical component and the micromechanical component manufactured using this method. In an example embodiment, the micromechanical component thereby includes a sensor substrate and a cap applied thereon. To create the cap, a plurality of openings is introduced into a cap substrate in a delimited area on the surface of the front side, e.g., in the form of microperforations (diameter a few μm). During the creation of these openings, however, care must be taken that the openings end in the cap substrate, i.e., they do not go all the way through the cap substrate and are therefore shallow. The cap substrate processed in this manner is subsequently applied to the sensor substrate, whereby the front side of the cap substrate including the plurality of openings is directed toward the sensor substrate. Finally, a portion of the cap substrate is removed from its back side, e.g., by back-thinning, a grinding process or another semiconductor process suitable for this. The removal of the cap substrate material from the back side creates access to the openings.

With this manufacturing method, therefore a cap of a sensor substrate may be created that has openings for a media access without damaging or clogging up these openings during the application process. The sensor structures situated on the sensor substrate and covered with the cap may also be protected during the manufacturing process by the initially closed openings.

This process makes possible, in particular in a molding process in which the cap and the sensor substrate are initially molded, a greater reliability of the manufacturing process since the covered sensor element cannot be damaged nor can the openings be closed.

Moreover, the subsequent back-thinning or grinding of the back side of the cap substrate also makes it possible to create very thin caps.

In one further embodiment of the present invention it may be provided that, in the delimited area in which the plurality of openings is created, a recess is initially created by removing some of the cap substrate material. This has the advantage that the openings are somewhat recessed from an enclosing frame. A configuration of this type has advantages during processing, in that the delimited area, which is weakened by the openings, is protected against direct mechanical contact with the sensor substrate. Moreover, a cavity may be created between the cap and sensor substrate by the projecting frame. This cavity or the distance between the openings and the sensor substrate may also be utilized by attaching a component directly to the sensor substrate inside the cavity.

However, a cavity of this type may also be achieved by a recess in the sensor substrate, e.g. during the creation of a sensor structure.

The placement of the delimited area in the cap substrate above a sensor structure created in the sensor substrate is particularly advantageous. For example, a diaphragm or an oscillating structure may be formed in the sensor substrate.

To place the cap substrate on the sensor substrate, as mentioned above, a frame is provided that encloses the delimited area. Even without a recess, i.e., a depression of the delimited area, this frame may be used to establish the connection to the sensor substrate. This may take place, for example, with the aid of a bonding process or an adhesive process.

To create the openings, a semiconductor process such as an etching process, e.g., a trench etching process, is used. With the aid of a process of this type, openings with very small diameters may be created with reasonable effort. Since these openings are intended to provide media access to the sensor element situated below them, the choice of a suitable diameter must take the intended use into consideration. However, these openings should primarily keep dust, dirt and fluids such as water away from the sensor element, although gaseous media may pass through unhindered.

On account of the use of a plurality of openings, the clogging of individual openings is not critical in terms of the function of the media passage.

Additional advantages arise from the following description of exemplary embodiments.

### BRIEF DESCRIPTION OF THE DRAWINGS

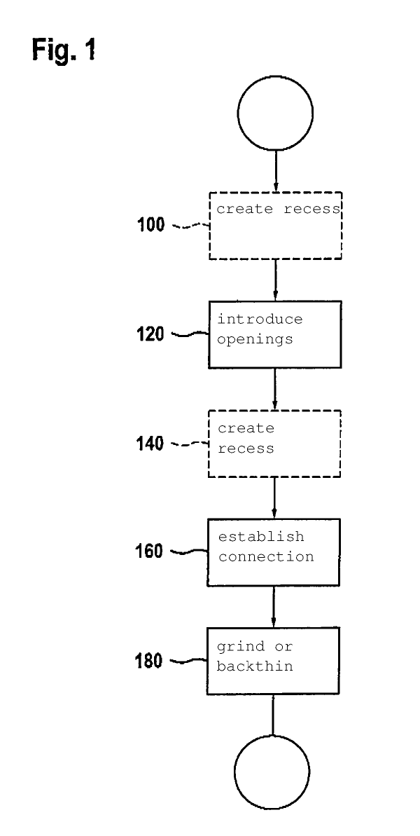

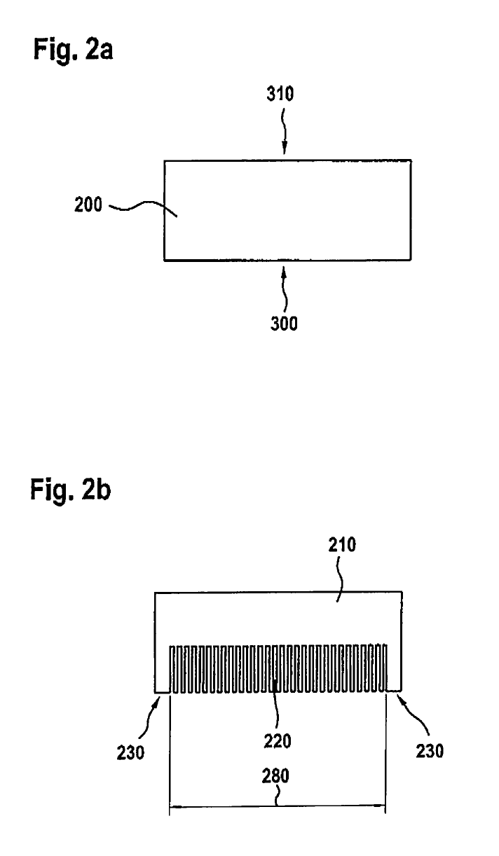

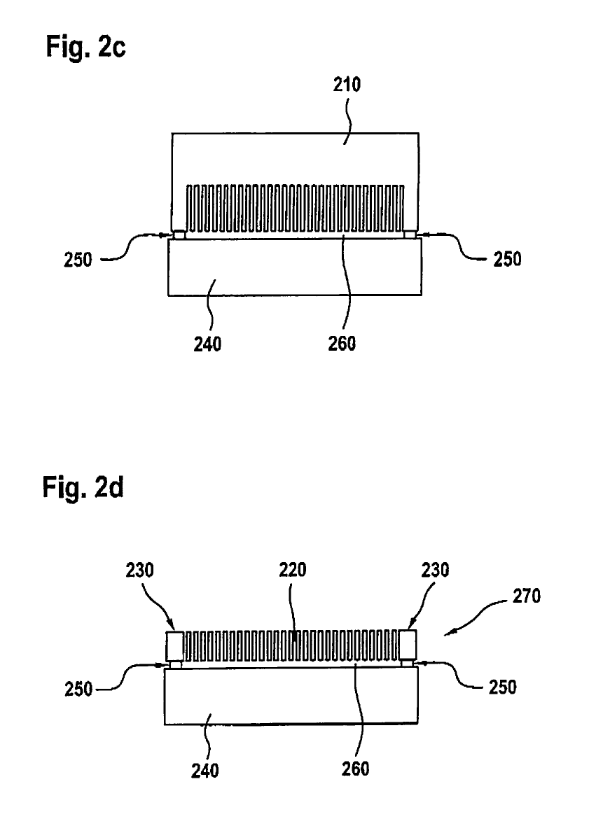

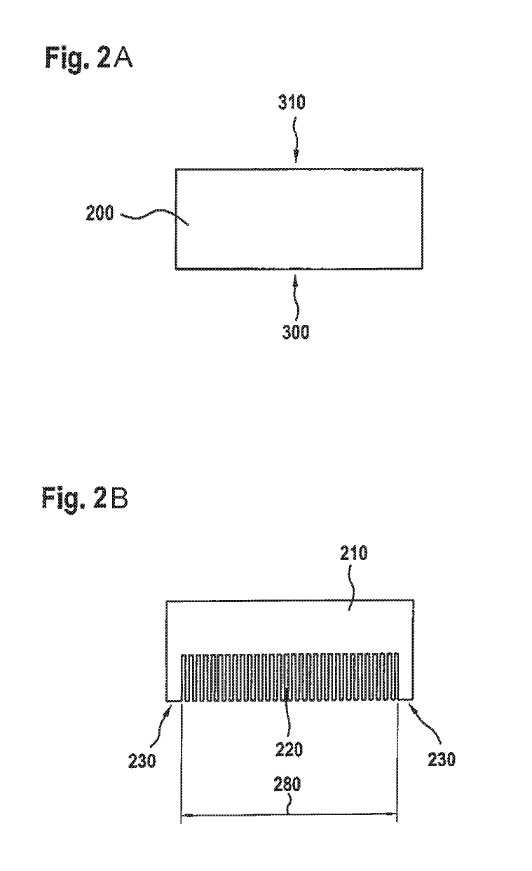

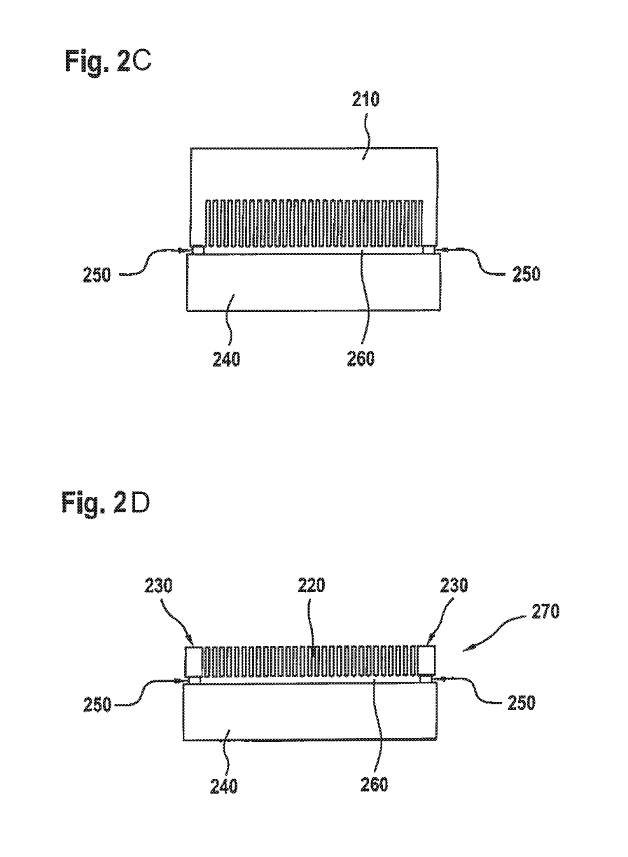

The method according to the present invention is described with reference to the accompanying FIG. 1. The individual method steps are also illustrated in FIGS. 2A-2D.

### DETAILED DESCRIPTION OF EXAMPLE EMBODIMENTS

For the manufacture of the component according to the present invention, in a method step 120 (see FIG. 1) in a cap substrate 200 (see FIG. 2a) made of silicon, for example, a first area 280 of front side 300 (see FIG. 2b) is defined into which a plurality of openings 220 is introduced. The depth of openings 220 is coordinated with the depth of cap substrate 200 in such a way that openings 220 end inside cap substrate 200. It is furthermore provided that this delimited area (280) has a frame 230 with the aid of which, in the next method step 160, a connection with the underlying sensor substrate 260 is established.

Cap substrate 210 provided with openings 220 is subsequently placed on sensor substrate 240 in method step 160 (see FIG. 2c). For this purpose, frame 230 acts as a connecting element, optionally with an adhesive or a bonding material 250. Between sensor substrate 240 and cap substrate 210, a cavity 260 may be provided in the vicinity of openings 220, i.e., in delimited area 280. This cavity 260 may be achieved by keeping cap substrate 210 at a distance from sensor substrate 240 with the aid of the adhesive, a bonding material 250 or a spacer. Alternatively, however, before the creation of the openings in method step 120, a recess may be created in delimited area 280 with an additional process step 100, so that openings 220 may be recessed in relation to frame 230. In an additional alternative, a recess may be created to form cavity 260 in sensor substrate 240 with respect to delimited area 280.

In final method step 180, cap substrate 210 is ground or back-thinned from its back side 310. As a result of this removal of material, the openings are opened toward the back side, so that media access from the surroundings into cavity 260 and/or to a sensor element situated in the sensor substrate 240 becomes possible (see FIG. 2d).

FIG. 2b shows only a cross-section through cap substrate 210 including openings 220 situated therein. It is expressly noted, however, that openings 220 do not necessarily have to be created in one row. Instead, openings 220 may also be configured in the form of an array, i.e., the openings may be lined up with one another in both lateral directions. Openings 220 may be provided in a geometric pattern as well as in a randomly generated pattern.

As noted above, in step 160 a sensor element or a sensor structure may be provided in sensor substrate 240. For this purpose, diaphragms are particularly well-suited for a diaphragm sensor, e.g. a pressure sensor or a gas sensor, or even movable structures such as acceleration and/or rotation rate sensors, for example. In a further configuration, the sensor element may be situated in sensor substrate 240 recessed from its surface. This has the advantage that cap 270 forms a cavity 260 with frame 230 and openings 220 together with the sensor substrate without the need for further measures.

What is claimed is:

1. A method for manufacturing a micromechanical component, the micromechanical component including a sensor substrate and a cap, the method comprising:
creating a plurality of openings in at least a delimited area in a surface of a front side of a cap substrate, the openings having a depth that is less than a thickness of the cap substrate;
placing the cap substrate on a sensor substrate, the front side of the cap substrate being oriented with the plurality of openings toward the sensor substrate; and
removing a portion of a back side of the cap substrate to open up the openings and to form the cap.

2. The method as recited in claim 1, wherein before the creating of the openings, performing:
creating a recess in the delimited area of the cap substrate by removing a portion of the material of the cap substrate.

3. The method as recited in claim 1, further comprising:
creating a sensor structure in the sensor substrate, the plurality of openings being situated above the sensor structure in the delimited area in the surface of the front side of the cap substrate when the cap substrate is placed on the sensor substrate.

4. The method as recited in claim 1, wherein the cap is placed on the sensor substrate in such a way that the sensor substrate encloses a cavity.

5. The method as recited in claim 1, wherein the delimited area in the surface of the front side of the cap substrate is created in such a way that the delimited area is surrounded by a frame, the cap substrate being fastened to the sensor substrate with the aid of the frame using an adhesive process or a bonding process.

6. The method as recited in claim 1, wherein the openings are created using a semiconductor process, the semiconductor process being a trench etching process.

7. The method as recited in claim 1, wherein a portion of the back side of the cap substrate is removed with the aid of a back-thinning or a grinding process.

8. The method as recited in claim 1, wherein the lateral dimension of the openings is selected in such a way that the passage of gaseous media is possible.

9. A micromechanical component, comprising:
a sensor substrate; and
a cap having, in a delimited area, a plurality of openings and a frame around the openings, the cap being situated on the sensor substrate with the aid of the frame, the openings formed on the side facing the sensor substrate and the cap having been back-thinned or ground from a side facing away from the sensor substrate.

10. The micromechanical component as recited in claim 9, wherein the delimited area has a recess with respect to the frame on the side facing the sensor substrate.

11. The micromechanical component as recited in claim 9, wherein the sensor substrate has a sensor structure, the openings of the cap being situated above the sensor structure.
